(19) United States
(12) Patent Application Publication
(10) Pub. No.: US 2006/0070653 A1
(43) Pub. Date: Apr. 6, 2006

(54) Nanostructured composite photovoltaic cell

(75) Inventors: Scott A. Elrod, La Honda, CA (US); Karl A. Littau, Palo Alto, CA (US); Thomas Hantschel, Menlo Park, CA (US); Raj B. Apte, Palo Alto, CA (US); David K. Biegelsen, Portola Valley, CA (US)

Correspondence Address: Jude A. Fry;FAY, SHARPE, FAGAN MINNICH & McKEE, LLP, SEVENTH FLOOR, 1100 SUPERIOR AVENUE, CLEVELAND, OH, 44114-2579, US

(73) Assignee: PALO ALTO RESEARCH CENTER INCORPORATED

(21) Appl. No.: 10/957,946

(22) Filed: Oct. 4, 2004

(51) Int. Cl. H01L 31/00

(52) U.S. Cl. 136/263; 136/252; 438/85; 438/82

(57) ABSTRACT

In accordance with one aspect of the present application, a solar photovoltaic cell is disclosed. The semiconductor material of the solar photovoltaic cell includes an inter-digitated nanostructure of a charge transport material and an optical absorbing material. The charge transport material is formed by anodization of a metal, preferably a transition metal. The resultant charge transport material has an array of discrete, substantially parallel and cylindrical pores formed therein. These pores are filled with the optical semiconductor material, which can include a solution of organic semiconducting materials or an inorganic semiconducting oxide material.

### BACKGROUND

The present disclosure relates to semiconductor devices, and more particularly, to solar photovoltaic cells.

A photovoltaic cell is a component in which light is converted directly into electric energy. A photovoltaic cell comprises at least one light-absorbing layer and a charge transport layer, as well as two electrodes. If the converted light is sunlight, the photovoltaic cell is a solar cell.

A heterojunction photovoltaic cell is one in which two dissimilar materials are used to generate the bias field and induce charge separation between generated electrons and holes.

A heterojunction photovoltaic cell comprises at least one light-absorbing layer and a charge transport layer, as well as two electrodes. If the converted light is sunlight, the photovoltaic cell is a solar cell.

Presently, a wide variety of semiconductor materials can be used for conversion of the sun's electromagnetic energy into electricity for thin film photovoltaic cells. For example, homojunctions of single semiconductor materials are available, such as silicon, cadmium telluride and copper indium diselenide.

Silicon is problematic in that it is relatively expensive. Other of these materials are toxic.

For solar photovoltaic cells, one would ideally want to use low-cost, non-toxic and abundant source materials and process these materials at low temperature on inexpensive substrates. The mobilities of such materials are often poor. For example, copper oxide (CuO) has a nearly ideal band gap (1.65 eV) for a solar photovoltaic device, but has a low mobility when oxidized at about 400-500° C. (i.e., 10⁻² cm²/V-sec.).

One approach that is known for making inexpensive photovoltaic cells is one where nanoporous titania films are filled with organic semiconductors. When the organic semiconductor or a sensitizing dye absorbed on the titania surface absorbs light, electron transfer to the titania takes place before the photogenerated electrons and holes recombine. The electrons then travel through the titania to an electrode on one side of the film, while the holes travel through the organic semiconductor (in the case of a polymer solar cell) or to an electrolyte (in the case of a dye-sensitized solar cell) to an electrode at the other side of the film.

The titania film used in conjunction with these photovoltaic cells can be made in a number of ways. For example, it can be made by doctor-blading a paste of titania nanocrystals and then sintering them together. The organic semiconductor is then incorporated into the pores of the titania film by spincasting.

Another method for making titania films having a pore structure is described by Coakley et al. in an article entitled “Infiltrating Semiconductor Polymers Into Self-Assembled Mesoporous Titania Films for Photovoltaic Applications,” Adv. Funct. Mater. 2003, 13, No. 4, April, the entire disclosure of which is herein incorporated by reference. The authors disclose that the films are made by dip-coating substrates with a solution of a titania sol-gel precursor and a structure-directing block copolymer. After the precursor and block copolymer co-assemble into an ordered mesostructure, the block copolymer is removed as the films are calcined at temperatures in the range of approximately 400-450° C.

A semiconducting polymer regioregular poly(3-hexylthiophene) (RR P3HT) is subsequently incorporated into the titania pores by spincasting a film of the polymer on top of the titania film and then heating at a temperature in the range of approximately 100-200° C.

The authors acknowledge that these parameters have not been optimized for photovoltaic applications. In this regard, performance of these devices in photovoltaic applications is thought to be limited by the quasi random nature of the pores in the TiO₂. More particularly, these organic photovoltaic cells employ a random matrix of the interconnected TiO₂ fibers in close physical proximity (≦20 nm) to the semiconductive polymer.

With particular reference to the photovoltaic cell disclosed in Coakley et al., electron-hole pairs are generated by optical absorption in the conductive polymer, and the electrons are subsequently pulled into the TiO₂ by the field resulting from the mismatch in the electron affinities of the TiO₂ and the conductive polymer. Close proximity is required to split the exciton (electron-hole pair) in the semiconductive polymer before recombination occurs. The tight geometry and random orientation of the small pores (≦20 nm) of the cell make it difficult for the molecules of the conductive polymer to align and give their maximum mobility for hole transport to the electrode. For example, chain kinks function as charge traps. Moreover, pore-filling of the TiO₂ is also a challenge due to their small size.

Thus, the need exists for a nanostructured composite photovoltaic cell which is fabricated from low-cost, non-toxic, abundant source materials. The nanostructured composite photovoltaic cell should efficiently extract charge from the semiconductor, while providing a sufficient path length for optical absorption.

The present disclosure contemplates a new and improved solar photovoltaic cell and method which overcomes the above-referenced problems and others.

### BRIEF DESCRIPTION

In accordance with one aspect of the present disclosure, a solar photovoltaic heterojunction device is disclosed. The solar photovoltaic heterojunction device includes an interdigitated nanostructure of a charge transport material and an optical absorbing material. The charge transport material has an array of discrete, substantially parallel and cylindrical pores formed therein. The pores are filled with the optical absorbing material. A first transparent electrode is disposed on a top surface of the inter-digitated nanostructure. A second electrode is disposed on a bottom surface of the inter-digitated nanostructure.

In accordance with another aspect of the present disclosure, a method for making a semiconductor layer for a solar photovoltaic cell is disclosed. A charge transport material is provided that has an array of discrete, substantially parallel and cylindrical pores formed therein. The pores are filled with an optical absorbing material to create an inter-digitated nanostructure of the charge transport material and the optical absorbing material.

In accordance with yet another aspect of the present disclosure, a method for making a solar photovoltaic cell is disclosed. A transition metal is anodized to form an oxide of the transition metal. The anodization results in discrete, substantially parallel and cylindrical pores in the transition metal oxide. The pores of the transition metal oxide are filled with an optical absorbing material to form an inter-digitated nanostructure of the transition metal oxide and the optical absorbing material. A transparent electrode is formed on a top surface of the inter-digitated nanostructure. Another electrode is formed on a bottom surface of the inter-digitated nanostructure.

### BRIEF DESCRIPTION OF THE DRAWINGS

The embodiments disclosed herein may take form in various components and arrangements of components, and in various steps and arrangements of steps. The drawings are only for purposes of illustrating embodiments and are not to be construed as limiting the embodiment.

FIG. 1 is a cross-sectional view of a solar photovoltaic cell according to an embodiment of the present disclosure;

FIG. 2 is a cross-sectional view of a second solar cell according to a second embodiment of the present disclosure; and

FIG. 3 is a cross-sectional view of a solar cell according to a third embodiment of the present disclosure.

### DETAILED DESCRIPTION

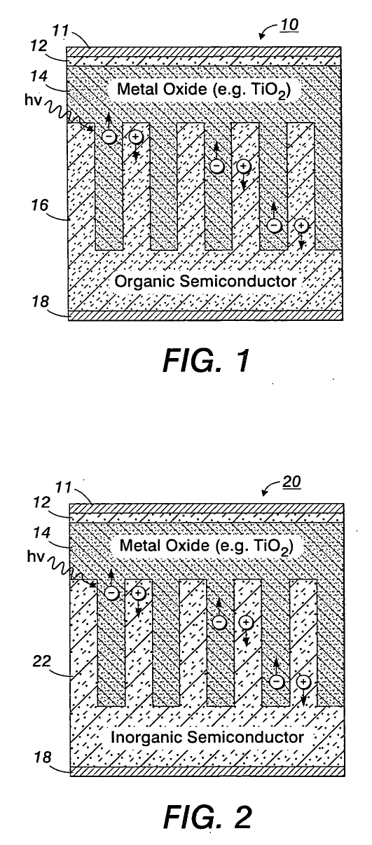

Referring to FIG. 1, a solar photovoltaic cell 10 is illustrated. The photovoltaic cell 10 includes an electrically conductive support formed of an optically transparent substrate 11 and transparent electrically conductive film 12.

The material used in the substrate 11 is not particularly limited and can be various kinds of transparent materials, and glass is preferably used.

The material used in the transparent electrically conductive film 12 is also not particularly limited, and it is preferred to use a transparent electrically conductive metallic oxide electrode such as fluorinated tin oxide (SnO₂:F), antimony-doped tin oxide (SnO₂:Sb), indium tin oxide (ITO), aluminum-doped zinc oxide (AnO:Al) and gallium-doped zinc oxide (ZnO:Ga). The preferred materials for the transparent electrically conductive film are ITO or fluorinated tin oxide.

Examples of the method for forming the transparent electrically conductive film 12 on the substrate 11 include a vacuum vapor deposition method, a sputtering method and a CVD (Chemical Vapor Deposition) method using a component of the material, and a coating method by a sol-gel process. Preferably, the electrically conductive support is formed by sputter depositing ITO on a glass substrate, using process conditions well-known to those of ordinary skill in the art.

Disposed atop the transparent electrically conductive film 12 is an inter-digitated nanostructure of a charge transport material 14 and an optical absorbing material 16.

The charge transport material 14 preferably is an oxide of a metal. The term metal refers to, in the Periodic Table, elements 21-29 (scandium through copper), 39-47 (yttrium through silver), 57-79 (lanthanum through gold), all known elements from 89 (actinium), in addition to aluminum, gallium, indium and tin. The metal is preferably a transition metal. In particular, titanium or tungsten may be used as the transition metal.

The solar photovoltaic device 10 is fabricated by sputter depositing a layer of the metal on the formed electrically conductive support. In addition, electroplating, CVD or evaporation could be used for forming the layer of the metal on the electrically conductive support. The metal has a thickness of about 100 nm to about 1000 nm. Anodic oxidation of the metal is effected to form the charge transport material 14 having discrete, hollow, substantially cylindrical pores. With reference to titanium as the metal, well-aligned titanium oxide pore arrays are obtained through titanium anodization in hydrogen fluoride (HF) solution as disclosed by Gong et al. in an article entitled “Titanium Oxide Arrays Prepared by Anodic Oxidation,” J. Mater. Res., Vol. 16, No. 12, December 2001, the disclosure of which is totally incorporated herein by reference.

The resulting pores are substantially straight, with a controllable pore diameter ranging from 10 to 100 nm, preferably about 20 to about 40 nm if the optical absorber is a semiconductive polymer; however, as understood by one of ordinary skill in the art, pore diameter is dependent on the desired characteristics of the optical absorber. Preferably, the diameter of the pore is shorter than the recombination distance in the optical absorbing material 16. The resulting pores also include a high aspect ratio (i.e., depth/width). For example, the aspect ratio of the pores ranges from about 3:1 to about 10:1.

With reference to titania as the charge transport layer 14, high-purity (99.99%) titanium is sputter deposited on the electrically conductive support 12. Alternatively, the titanium can be deposited by electroplating, CVD or evaporation. The anodization is conducted at room temperature (18° C.) with magnetic agitation. The aqueous solution contains from 0.5 to 3.5 wt. % HF. As is readily understood by one of ordinary skill in the art, different anodization temperatures, HF concentrations and chemical solutions can be used for the anodization step depending upon the desired outcome.

If desired, a second oxidation step can be performed to ensure that the charge transport material 14 is fully oxidized, and as a wide bandgap semiconductor, transparent to most of the solar spectrum.

The anodizing voltages are preferably kept constant during the entire process but may be changed during the anodizing step. At increased voltages, discrete, hollow, substantially parallel and cylindrical pores appear in the titanium oxide films. In particular, titanium oxide pore arrays are obtained under anodizing voltages ranging from 10-40 volts as dependant on the HF concentration, with relatively higher voltages needed to achieve the tube-like structures in more dilute HF solutions. The final length of the pores is independent of the anodizing time.

With reference to FIG. 1, the regular structure of the pores makes it easier to intercalate ordered organic molecules and achieve maximum mobility for hole transport. The regular structure also allows for optimization of the pitch with respect to the charge collection distance.

With further reference to FIG. 1, the optical absorbing material 16 is any solution of organic semiconducting materials. Examples of suitable materials include a fluorescent pigment, such as perylene.

Other suitable materials would include C₆₀, C₇₀, C₇₆, C₈₄, C₉₀, C₁₂₀, C₂₄₀ and the like. In the fullerene molecules, an even number of carbon atoms are arranged to form a closed hollow cage. Each atom is trigonally linked to its three neighbors by bonds that form a polyhedral network, consisting of 12 pentagons and n-hexagons. In fullerene C₆₀, e.g., all 60 atoms are equivalent and lie on the surface of a sphere with the atoms at the vertices of a truncated icosahedron, thus forming a soccer-ball pattern. The 12 pentagons are isolated and interspersed symmetrically with 20 linked hexagons to form a soccer-ball shape.

Derivatives of fullerenes are known. For example, they can be multiply hydrogenated, methylated, fluorinated or ammoniated. They may form exohedral complexes in which an atom or a group of atoms is attached to the outside of the cage. In addition, they may form endohedral complexes, in which a metal atom, e.g., lanthanum, potassium, calcium, cesium or the like is trapped inside.

All of these various fullerenes and derivatives thereof are contemplated to be used within the scope of the present exemplary embodiment. The term fullerene, as used herein, conotes all of the aforementioned fullerenes as well as the derivatives thereof. The term “fullerene” as used herein connotes closed-cage molecules comprised solely of carbon atoms which contain at least 60 carbon atoms. The derivatives are structures derived from this basic form.

The fullerenes are commercially prepared or are prepared by art recognized techniques utilizing the teachings in the above-identified patents. Various fullerenes products are commercially available through Bucky USA.

In addition, semiconducting polymers can be used. Suitable semiconducting polymers include, but are not limited to, poly(phenylenevinylene)-based polymers and polythiophene-based polymers, and mixtures or copolymers thereof. These polymers are well-known in the art.

Particularly advantageous semiconductive polymers are included in the American Dye Source, Inc. line of polymers and include high molecular weight regioregular and low metal content poly(3-alkyl thiophene) and poly(3-methyl-4-alkyl thiophene).

Filling the pores of the charge transport material 14 with the perylene or C₆₀ ND modified fullerenese is accomplished by spin casting a solvent solution of the perylene or C₆₀ modified fullerene followed by heating using the approach set out in Coakley et al. in the article entitled “Infiltrating Semiconductor Polymers Into Self-Assembled Mesoporous Titania Films for Photovoltaic Applications,” Adv. Funct. Mater. 2003, 13, No. 4, April, the entire disclosure of which is herein incorporated by reference.

Filling the pores of the transparent charge transport material 14 with the semiconductive polymer material can be done by spincasting as is well understood by one of skill in the art. In particular, a film of the polymer is spincasted on top of the titania film and then heated at temperatures in the range of 100-200° C. Following heat treatment, the excess polymer that did not infiltrate the pores of the charge transport material 14 is removed by rinsing in toluene. Alternatively, the titania film can be placed in contact with a liquid solution of the polymer by direct submersion.

Alternatively, another method that may be used is filling of the pores in a vacuum to minimize the presence of trapped air in the pores. This process involves placing the sample in a vacuum to remove air from the pores, and applying a solution with the polymer to the surface while still under vacuum. Then by bringing the sample back to atmospheric pressure, the pressure differential between any unfilled pores and the atmosphere exerts a force to drive the polymer material into the pores.

Electrode 18 is deposited on the cell 10 as indicated in FIG. 1. Examples of electrode 18 include platinum, gold, silver, graphite and aluminum. Electrode 18 is deposited using well-known processes, including a vacuum evaporation method, a sputtering method or a CVD (Chemical Vapor Deposition) method.

FIG. 2 differs from the embodiment of FIG. 1 in that the optical absorbing material 22 of FIG. 2 is an inorganic semiconductor material. Examples of the inorganic semiconductor materials with appropriate bandgap energies are cupric oxide (CuO) and cuprous oxide (Cu₂O).

The pores in the charge transport material 14 of FIG. 2 are filled with the optical absorbing material 22 by processes well-known and understood to those of ordinary skill in the art. Such processes for filling the pores of the charge transport material 10, include sputtering, electroplating, electroless plating, reflow CVD and evaporation.

For example, the optical absorbing material 22 of FIG. 2 is preferably a copper oxide (Cu₂O or CuO). Copper can be easily sputtered and, using well-known plasma conditions, such as high-density plasma (HDP) sputtering with large substrate bias, the copper atoms can be directed normal to the incident surface. Moderate aspect ratios such as 2 or 3:1 or even higher can be filled using sputtering.

In HDP sputtering the argon working gas is excited into a high-density plasma, which is a plasma having an ionization density of at least 10″ cm⁻³ across the entire space the plasma fills except the plasma sheath. Typically, an HDP sputter reactor uses an RF power source connected to an inductive coil adjacent to the plasma region to generate the high-density plasma. The high argon density causes a significant fraction of sputtered atoms to be ionized. If the pedestal electrode supporting the device being sputter coated is negatively electrically biased, the ionized sputter particles are accelerated toward the device to form a directional beam that reaches deeply into the narrow holes.

Electrochemical deposition or electroplating is the standard production method for depositing copper into trenches and vias in the semiconductor industry and can be used for filling the pores of the charge transport material 14 with the optical absorbing material 22. High aspect ratio filling is accomplished as is well-known to those of skill in the art using additives to the electroplating bath such as accelerants (e.g., sulfur-containing compounds) and surfactants (e.g., nitrogen-containing compounds) to enhance growth at the bottom and suppress it near the top. As is well understood in the art, electroplating requires a continuous seed layer in order to supply the required voltage across the entire substrate.

In this regard, a copper seed layer is deposited using, e.g., physical vapor deposition (PVD) methods, and the seed layer is typically deposited on a barrier layer. A seed layer deposition may require a pre-clean step to remove contaminants. The pre-clean step could be a sputter etch using an argon plasma, typically performed in a process chamber separate from the PVD chamber used to deposit the seed layer.

Electroless plating techniques can also be used to fill the charge transport material 10. The reaction is preferably driven by a redox reaction in the bath allowing plating on isolated features. The reaction is naturally selective and will only plate copper on itself or an activated surface such as TiO₂.

A typical electroless metal plating solution comprises a soluble ion of the metal to be deposited, a reducing agent and such other ligands, salts and additives that are required to obtain a stable bath having the desired plating rate, deposit morphology and other characteristics. Common reductants include hypophosphite ion, formaldehyde, hydrazine or dimethylamine-borane. The reductant reacts irreversibly at the catalyst core to produce an active hydrogen species. The choice of electroless metal plating solution is determined by the desired properties of the deposit, such as conductivity, magnetic properties, ductility, grain size and structure and corrosion resistance.

If the charge transport material 14 is heated to a temperature where copper has significant surface mobility, pores may be filled by diffusion of the copper atoms. This reflow process can be done in situ. If the feature is lined with a thin copper layer such as from CVD, sputtering more copper on the feature at temperatures of 3000 to 400° C. can lead to filled pores. High aspect ratio holes can be filled in this manner.

Copper CVD can also be used for filling of the pores of the charge transport layer 10 using metallo-organic precursors. In this manner, Cu (HFAC) TMVS [copper(I) hexafluoroacetylacetonate vinyltrimethyl silane] is the main precursor used and is commercially available from Schumacher in a proprietary blend. The reaction requires 2 Cu (HFAC) TMVS molecules. One of the copper atoms is converted to Cu(II) (HFAC)₂, while the other is deposited as copper. The film is quite conformal even at high aspect ratios. Selective methods of deposition are possible where the reaction only takes place on active sites, such as an exposed metal pad. This process allows “bottom up” filling of very high aspect ratio pores.

After filling of the pores of the charge transport material 14, the resultant inter-digitated structure is oxidized by heat treatment to create a heterostructure between the charge transport material 14 and the optical absorbing material 22.

With specific reference to FIG. 2, the copper in the pores of the charge transport material 14 is oxidized to CuO or Cu₂O by heat treatment at 200-700° C. for a time ranging from several minutes to several hours depending upon the desired process conditions. For example, the charge transport material 14 is oxidized to CuO by heat treatment at about at 500° C. for five minutes on a hot plate. Alternatively, the copper is oxidized to Cu₂O by heat treatment at about 300° C. on a hot plate for about five minutes. As understood by one of skill in the art, different oxidation times, oxidation environments and oxidation may be used.

In addition, cuprous and cupric oxides can be directly electrodeposited from solutions of Cu(I) and Cu(II) salts. For example, CuO can be formed electrochemically from high pH (>10) copper sulfate electrolytic solutions stabilized by chelating agents such as tartaric acid. CuO is deposited directly on the anode of an electrochemical cell using such an electrolyte. Similar methods for Cu₂O are known to those of ordinary skill in the art.

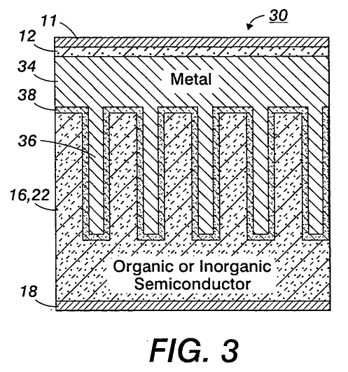

FIG. 3 differs from the embodiments of FIGS. 1 and 2 in that the charge transport material 34 is not completely oxidized during the anodization process. This configuration can be achieved by adjusting the anodization process conditions to achieve a relatively low density of pores per unit area, such that metal remains between the anodized regions. The resulting charge transport material 34 of FIG. 3 includes metal cores 36 within the discrete, substantially parallel pores. The outer section 38 of the pores is an oxide of the metal. This structure ensures improved accumulation of electrons in the charge transport material 34, given the decreased travel distance in the charge transport material 34. While providing a nearby conductor may improve the charge collection efficiency for electron-hole pairs that are generated, the structure will not allow photons to pass as readily from one pore to the next, thereby decreasing the light collection efficiency. The desirability of maintaining a residual amount of metal in the electron transport medium will depend on the detailed tradeoffs between charge transport and light gathering efficiency.

If desired, the solar photovoltaic cell 10, 20, 30 can also be sealed, for example, using an adhesive or a film.

Including the substrate, the photovoltaic cell 10, 20, 30 in FIGS. 1-3 generally has a thickness of from about 0.5 mm to about 2.0 mm.

To avoid reflection losses, the bottom side of the photovoltaic cell 10, 20, 30 in FIGS. 1-3 can be provided with an antireflection coating having one, two, or more layers.

To increase the light yield, the reverse side of the photovoltaic cell 10, 20, 30 in FIGS. 1-3 can be constructed in such a way that light is reflected back into the cell.

One embodiment would use concentrated sunlight to improve the solar cell efficiency, for example, by using mirrors or Fresnel lenses.

The cells of the exemplary embodiments can also be part of a tandem cell; in such devices a plurality of subcells convert light from different spectral regions into electrical energy.

The exemplary embodiment has been described with reference to the preferred embodiments. Obviously, modifications and alterations will occur to others upon reading and understanding the preceding detailed description. It is intended that the exemplary embodiment be construed as including all such modifications and alterations insofar as they come within the scope of the appended claims or the equivalents thereof.

1. A solar photovoltaic device which comprises:
an inter-digitated heterostructure nanostructure of a charge transport material and an optical absorbing material, the charge transport material having an array of discrete, substantially parallel and cylindrical pores formed therein, the pores filled with the optical absorbing material;
a first transparent electrode disposed on a top surface of the inter-digitated nanostructure; and
a second electrode disposed on a bottom surface of the inter-digitated nanostructure.

2. The photovoltaic device of claim 1, wherein the charge transport material is an oxide of a transition metal.

3. The photovoltaic device of claim 2, wherein the oxide of a metal is TiO₂ or WO₃.

4. The photovoltaic device of claim 1, wherein the pores have a diameter of about 20 nm to about 200 nm.

5. The photovoltaic device of claim 1, wherein the pores have an aspect ratio of about 3:1 to about 10:1.

6. The photovoltaic device of claim 1, wherein the optical absorbing material is a polymer semiconductor.

7. The photovoltaic device of claim 6, wherein the polymer semiconductor is thiophene or a derivative of thiophene.

8. The photovoltaic device of claim 1, wherein the optical absorbing material is an inorganic semiconductor.

9. The photovoltaic device of claim 8, wherein the inorganic semiconductor is an oxide of copper.

10. The photovoltaic device of claim 1, wherein the pores are filled by spincasting.

11. The photovoltaic device of claim 1, wherein the pores are filled by sputtering, electroplating, electroless plating, reflow, CVD or evaporation.

12. A method for making a semiconductor layer for a solar photovoltaic cell comprising:
providing a charge transport material having an array of discrete, substantially parallel pores formed therein; and
filling the pores with an optical absorbing material to create an inter-digitated nanostructure of the charge transport material and the optical absorbing material.

13. The method of claim 12, wherein the pores have an aspect ratio of about 3:1 to about 10:1.

14. The method of claim 12, wherein the step of preparing the charge transport material is carried out by anodizing a transition metal.

15. The method of claim 14, wherein the transition metal is titanium or tungsten.

16. The method of claim 12, wherein the step of filling the pores is carried out by spincasting.

17. The method of claim 12, wherein the optical absorbing material is a semiconductive polymer.

18. The method of claim 12, wherein the optical absorbing material is an inorganic semiconducting oxide of a transition metal.

19. The method of claim 18, wherein the inorganic semiconducting oxide of the transition metal is an oxide of copper.

20. A method for making a solar photovoltaic cell, the method comprising:
anodizing a transition metal to form an oxide of the transition metal, the transition metal oxide having discrete, substantially parallel and cylindrical pores;
filling the pores of the transition metal oxide with an optical absorbing material to form an inter-digitated nanostructure of the transition metal oxide and the optical absorbing material; and
forming an electrode on a top surface and a bottom surface of the inter-digitated nanostructure, one of the electrodes being transparent.

21. The method of claim 20, including the step of oxidizing the inter-digitated nanostructure.

22. The method of claim 20, wherein the pores are filled by spincasting.

23. The method of claim 20, wherein the pores are filled by sputtering, electroplating, electroless plating, reflow, CVD or evaporation.

24. The method of claim 20, wherein the optical absorbing material is a semiconducting oxide of a transition metal.

25. The method of claim 24, wherein the semiconducting oxide of a transition metal is an oxide of copper.

26. The method of claim 20, wherein the transition metal is partially oxidized.
